(19) United States
(12) Patent Application Publication
(10) Pub. No.: US 2014/0284715 A1
(43) Pub. Date: Sep. 25, 2014

(54) METHOD OF MANUFACTURING SEMICONDUCTOR DEVICE

(71) Applicant: KABUSHIKI KAISHA TOSHIBA, Tokyo (JP)

(72) Inventor: Tatsuo FUKUDA, Hyogo (JP)

(73) Assignee: KABUSHIKI KAISHA TOSHIBA, Tokyo (JP)

(21) Appl. No.: 14/017,239

(22) Filed: Sep. 3, 2013

(30) Foreign Application Priority Data
Mar. 22, 2013 (JP) 2013-061136

(51) Int. Cl. H01L 29/06

(52) U.S. Cl. CPC H01L 29/0696; H01L 29/0619
USPC 257/339; 438/268

(57) ABSTRACT

According to one embodiment, in a method of manufacturing a semiconductor device, a plurality of first impurity layers of a second conductivity type are formed. A first epitaxial layer of a first conductivity type is formed. A plurality of second impurity layers of a second conductivity type are formed. Thereafter, a second epitaxial layer of a first conductivity type having a smaller thickness than the first epitaxial layer is formed. The first impurity layers of a second conductivity type and the second impurity layers of a second conductivity type are bonded to each other by heat treatment thus forming a plurality of pillar layers of a second conductivity type. A second semiconductor layer of a second conductivity type which is brought into contact with the pillar layers of a second conductivity type is formed over a surface of the second epitaxial layer.

### CROSS-REFERENCE TO RELATED APPLICATION

This application is based upon and claims the benefit of priority from Japanese Patent Application No. 2013-061136, filed Mar. 22, 2013, the entire contents of which are incorporated herein by reference.

### FIELD

Embodiments described herein relate generally to a method of manufacturing a semiconductor device.

### BACKGROUND

It is desirable that an insulation gate-type semiconductor device such as an IGBT (Insulated Gate Bipolar Transistor) or a MOSFET (Metal Oxide Semiconductor Field Effect Transistor) possess low ON resistance, high breakdown strength and high avalanche resistance. However, when the ON resistance is lowered, the depletion layer does not significantly extend into the drift layer of the insulation gate-type semiconductor device, resulting in lowered breakdown strength. To cope with this drawback, there has been adopted the super junction structure where a p-type semiconductor layer and an n-type semiconductor layer are alternately arranged in the drift layer in the direction parallel to a substrate. In the super junction structure, even when the carrier concentration in the n-type semiconductor layer through which an electron current flows and the dopant concentration in the p-type semiconductor layer through which a hole current flows are increased, the super junction structure functions as a pseudo low concentration layer as a whole and hence, the super junction structure is easily depleted. Accordingly, the insulation gate-type semiconductor device which has the super junction structure in the drift layer can lower the ON resistance while maintaining high breakdown strength. The insulation gate-type semiconductor device is used as a switching element in such a manner that the insulation gate-type semiconductor device is connected to a load having inductance such as a motor. When the MOSFET or the IGBT is switched to an OFF state from an ON state, an electromotive force attributed to inductance is imparted between the source and the drain of the MOSFET (between the emitter and the collector in the case of the IGBT). When a voltage which exceeds the breakdown strength is applied, avalanche breakdown occurs at a p-n junction between the p-type semiconductor layer and the n-type semiconductor layer in the super junction structure. A large quantity of electron current and a large quantity of hole current are generated by the avalanche breakdown. Accordingly, it is also desirable that the insulation gate-type semiconductor device such as the MOSFET and the IGBT possesses high avalanche resistance as well as high breakdown strength so as not to be broken by an electric current attributed to avalanche breakdown.

### DESCRIPTION OF THE DRAWINGS

FIG. 1 is a cross-sectional view of a semiconductor device according to a first embodiment;

FIG. 2A and FIG. 2B are cross-sectional views showing a part of manufacturing steps of the semiconductor device according to the first embodiment;

FIG. 3A to FIG. 3C are cross-sectional views showing a part of manufacturing steps of the semiconductor device according to the first embodiment;

FIG. 4A and FIG. 4B are cross-sectional views showing a part of manufacturing steps of the semiconductor device according to the first embodiment;

FIG. 5A and FIG. 5B are cross-sectional views showing a part of manufacturing steps of the semiconductor device according to the first embodiment;

FIG. 6 is a cross-sectional view of a semiconductor device according to a comparison example;

FIG. 7 is a graph showing an operational characteristic of the semiconductor device according to the embodiment and an operational characteristic of the semiconductor device according to the comparison example;

FIG. 8 is a cross-sectional view of a semiconductor device according to a second embodiment;

FIG. 9A and FIG. 9B are cross-sectional views showing a part of manufacturing steps of the semiconductor device according to the second embodiment; and

FIG. 10 is a cross-sectional view of a semiconductor device according to a third embodiment.

### DETAILED DESCRIPTION

Embodiments provide a method of manufacturing a semiconductor device which exhibits high breakdown strength, low ON resistance and high avalanche resistance.

In general, a method of manufacturing a semiconductor device according to one embodiment includes: forming a plurality of first impurity (i.e., doped) layers of a second conductivity type; forming a first epitaxial layer of a first conductivity type; forming a plurality of second impurity layers of a second conductivity type; forming a second epitaxial layer of a first conductivity type; forming a plurality of pillar layers of a second conductivity type; forming a second semiconductor layer of a second conductivity type; forming a third semiconductor layer of a first conductivity type; forming a gate electrode; forming a first electrode, and forming a second electrode.

In forming the plurality of first impurity layers of a second conductivity type, the plurality of first impurity layers of a second conductivity type are selectively formed with a surface of a first semiconductor layer of a first conductivity type by ion implantation. In forming the first epitaxial layer of a first conductivity type, the first epitaxial layer of a first conductivity type is formed over the first semiconductor layer. In forming the plurality of second impurity layers of a second conductivity type, the plurality of second impurity layers of a second conductivity type are selectively formed in a surface of the first epitaxial layer by ion implantation such that the second impurity layers are positioned above the first impurity layers of a second conductivity type in the second direction perpendicular to a surface of the first semiconductor layer. In forming the second epitaxial layer of a first conductivity type, the second epitaxial layer of a first conductivity type having a smaller thickness than the first epitaxial layer in the second direction is formed over the first epitaxial layer. Informing the plurality of pillar layers of a second conductivity type, the plurality of pillar layers of a second conductivity type are formed by extending the first impurity layers of a second conductivity type and the second impurity layers of a second conductivity type into each other in the second direction by heat treatment (thermal annealing). In forming the second semiconductor layer of a second conductivity type, the second semiconductor layer of a second conductivity type is brought into contact with the pillar layer of a second conductivity type and is formed within a surface of the second epitaxial layer. In forming the third semiconductor layer of a first conductivity type, the third semiconductor layer of a first conductivity type is selectively formed over a surface of the second semiconductor layer. In forming the gate electrode, the gate electrode is formed over the second semiconductor layer and the third semiconductor layer by way of a gate insulation film. In forming the first electrode, the first electrode which is electrically connected to the second semiconductor layer and the third semiconductor layer is formed. In forming the second electrode, the second electrode which is electrically connected to the first semiconductor layer is formed.

### EMBODIMENT

Hereinafter, embodiments are explained in conjunction with drawings. Drawings used in the explanation of the embodiments are schematic views for facilitating the understanding of the explanation. Shapes, sizes, the relationship in size and the like of the respective elements in the drawings are not always exactly equal to those of the elements in practical use and hence, shapes, sizes, the relationship in size and the like of the respective elements can be changed as required within a range where advantageous effects of exemplary embodiment can be acquired. In the explanation made hereinafter, a first conductivity type is an n type and a second conductivity type is a p type. However, these conductivity types may be reversed so that the first conductivity type is a p type and the second conductivity type is an n type. Although a semiconductor made of silicon is described herein as one example, the exemplary embodiment is also applicable to a semiconductor made of a compound such as SiC, GaN. Although an insulation film made of silicon oxide is disclosed herein as one example, the semiconductor may be formed using other insulation materials such as silicon nitride and silicon oxynitride. In expressing an n-type conductivity type by n⁺, n and n⁻, it is assumed that the concentration of n-type impurity is lower in this order of n⁺, n and n⁻. Also in expressing a p-type conductivity type by p⁺, p and p⁻, it is assumed that the concentration of p-type impurity is lower in this order of p⁺, p and p⁻. Although the explanation is made hereinafter by taking a MOSFET as the insulation gate type semiconductor device as an example, the respective exemplary embodiments are also applicable to an IGBT, an IEGT (Injection Enhanced Gate Transistor) or the like.

### First Embodiment

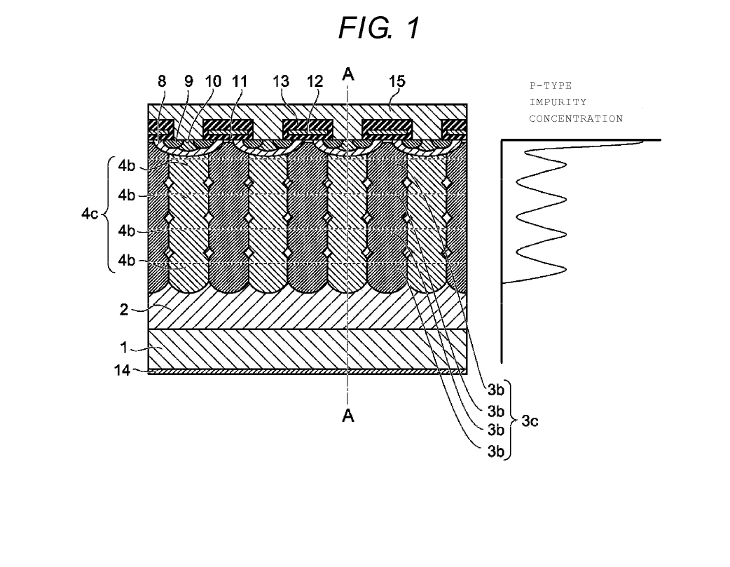

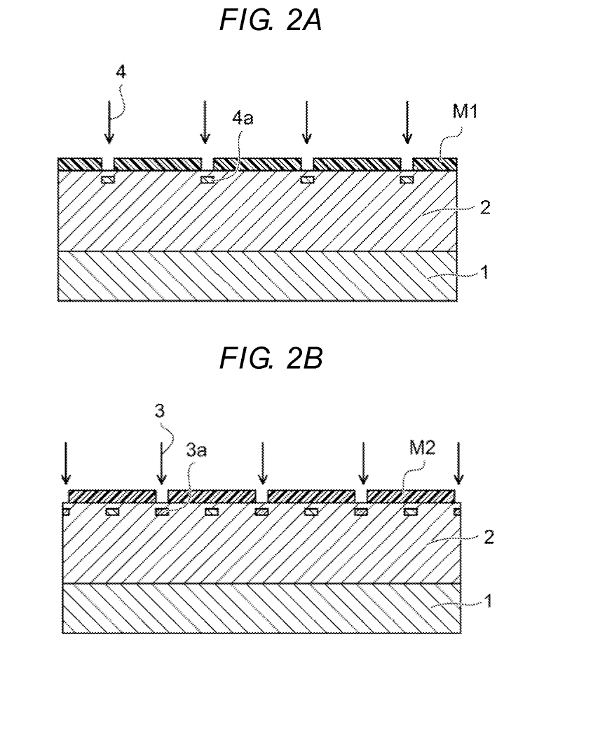

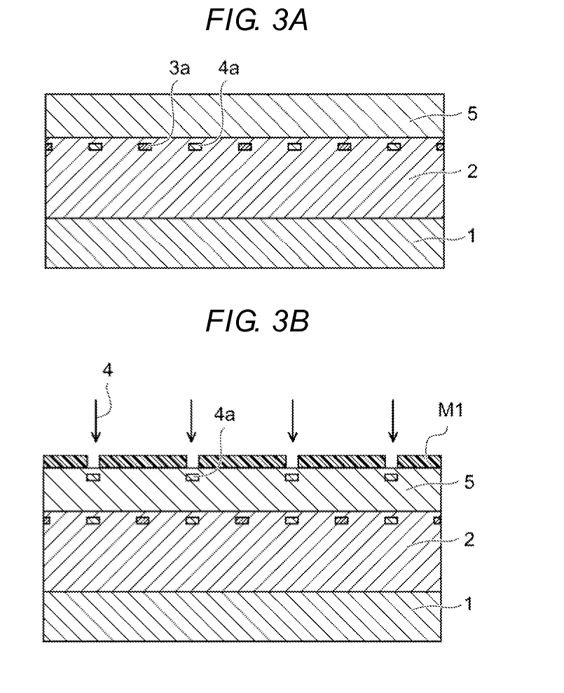

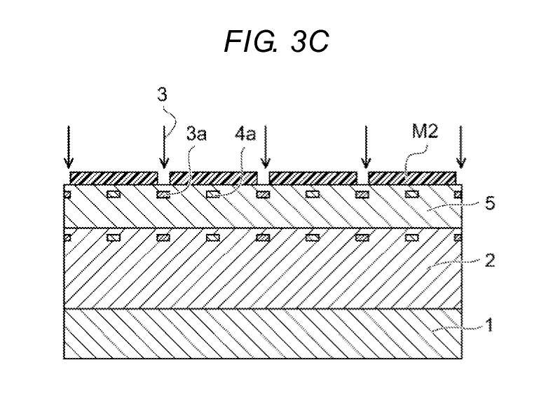

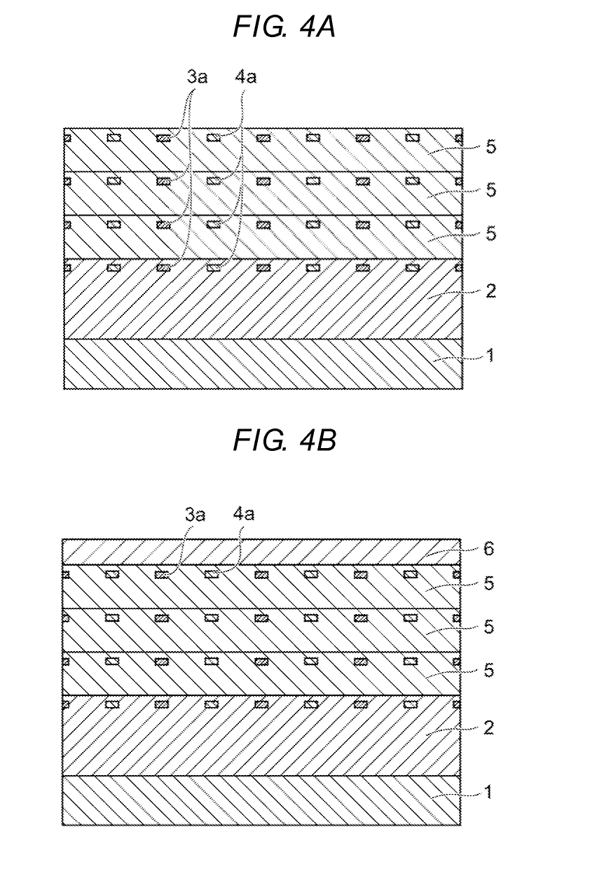

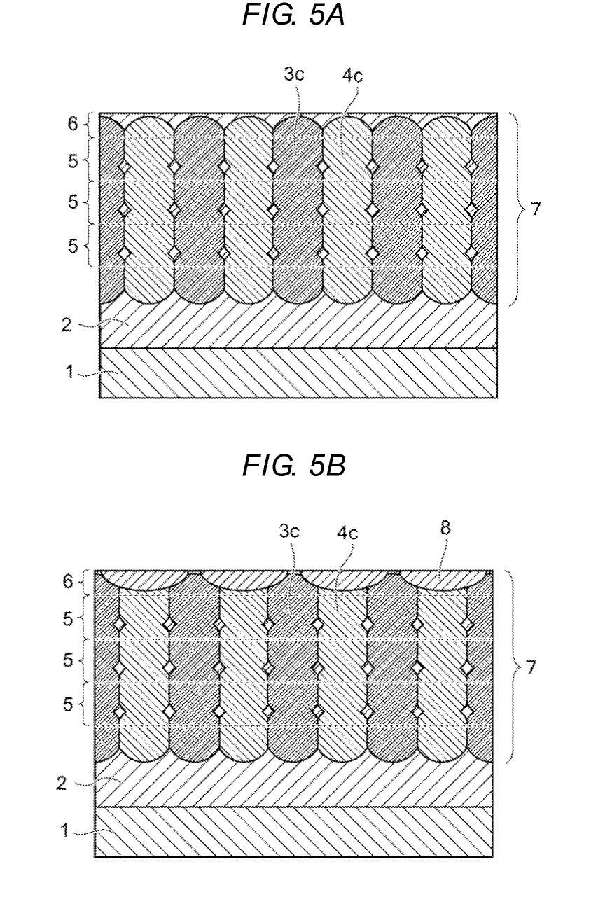

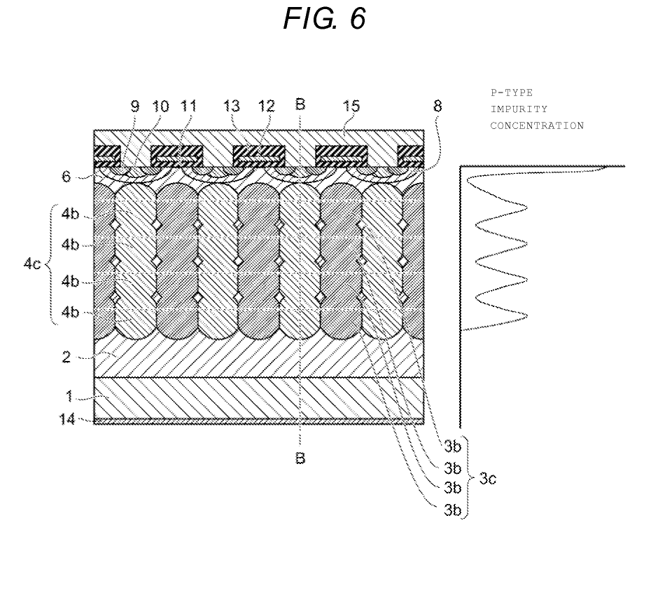

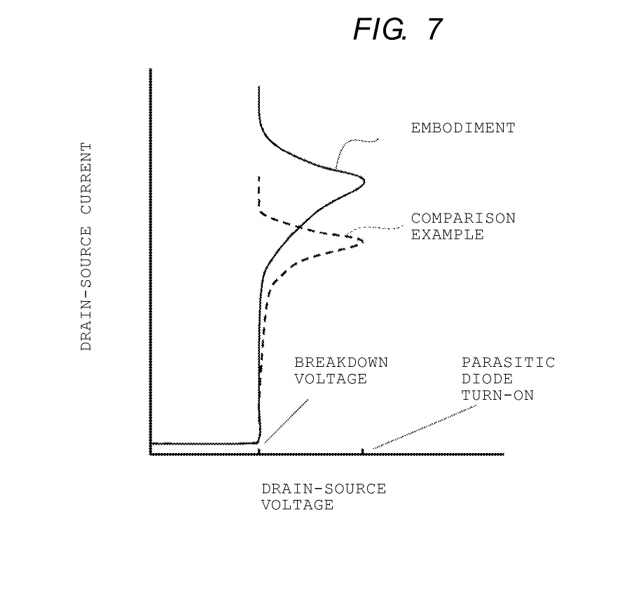

A semiconductor device and a method of manufacturing a semiconductor device according to a first embodiment are explained in conjunction with FIG. 1 to FIG. 7. FIG. 1 is a cross-sectional view of the semiconductor device according to the first embodiment. FIG. 2A and FIG. 2B, FIG. 3A to FIG. 3C, FIG. 4A and FIG. 4B, and FIG. 5A and FIG. 5B are views showing the semiconductor device according to the first embodiment in cross section in several steps of the method of manufacturing a semiconductor device. FIG. 6 is a cross-sectional view of a semiconductor device according to a comparison example. FIG. 7 is a graph where an operational characteristic of the semiconductor device according to the first embodiment and an operational characteristic of the semiconductor device according to the comparison example are compared to each other.

As shown in FIG. 1, the semiconductor device according to this embodiment is a MOSFET, and includes an n⁺-type semiconductor substrate 1, an n⁻-type semiconductor layer 2, n-type pillar layers 3c, p-type pillar layers 4c, p-type base layers 8, n⁺-type source layers 9, p⁺-type contact layers 10, gate insulation films 11, gate electrodes 12, interlayer insulation films 13, a source electrode 15, and a drain electrode 14. The semiconductor is made of silicon, for example.

The n⁻-type semiconductor layer 2 is formed over the n⁺-type semiconductor substrate 1, and is formed by epitaxial growth. The plurality of p-type pillar layers 4c and the plurality of n-type pillar layers 3c are formed over the n⁻-type semiconductor layer 2, and are arranged alternately in the first direction, which is parallel to a surface of the n⁻-type semiconductor layer 2, i.e., a plurality of stacks of n− type pillar layers extend from the n⁻-type layer 2, and the individual n-type stacks alternate across the surface of the n⁻-type layer 2 with individual p-type stacks of a plurality of stacks of p− type pillar layers extending into the n⁻-type layer 2.

The p-type pillar layer 4c is constituted of a plurality of p-type impurity diffusion layers 4b which are formed in the n⁻-type semiconductor layer 2, and first n⁻type epitaxial layers 5 and a second n⁻type epitaxial layer 6 which are formed over the n⁻-type semiconductor layer 2. The plurality of p-type impurity diffusion layers 4b are connected to each other in the second direction, which is perpendicular to the surface of the n⁻-type semiconductor layer 2.

In the same manner as the p-type pillar layers 4c, the n-type pillar layer 3c also comprises a plurality of n-type impurity diffusion layers 3b which are formed in the n⁻-type semiconductor layer 2, and in the first n⁻type epitaxial layers 5 and the second epitaxial layer 6 which are formed over the n⁻-type semiconductor layer 2. The number of the p-type impurity diffusion layers 4b and the number of the n-type impurity diffusion layers 3b are set to 4 in this embodiment. That is, the p-type pillar layer 4c is constituted of four stages or layers of the p-type impurity diffusion layers 4b, and the n-type pillar layer 3c is constituted of four stages or layers of the n-type impurity diffusion layers 3b.

The concentration of p-type impurity in the p-type pillar layers 4c and the concentration of n-type impurity in the n-type pillar layers 3c is higher than the concentration of n-type impurity in the n⁻-type semiconductor layer 2. An amount of p-type impurity which the p-type pillar layers 4c contain, and an amount of n-type impurity which the n-type pillar layers 3c contain, substantially equal in an arbitrary plane parallel to the surface of the n⁻-type semiconductor layer 2 are. The p-type pillar layers 4c and the n-type pillar layers 3c constitute the super junction structure where when an inverse bias is applied to a p-n junction between the p-type pillar layer 4c and the n-type pillar layer 3c, the p-type pillar layer 4c and the n-type pillar layer 3c are easily depleted.

A p-type base layer 8 is formed over an upper portion of each p-type pillar layer 4c and is electrically connected to each p-type pillar layer 4c. An n⁺-type source layer 9 is selectively formed over a surface of the p-type base layer 8. The concentration of n-type impurity in the n⁺-type source layers 9 is set higher than the concentration of n-type impurity in the n⁻-type semiconductor layer 2 and the concentration of n-type impurity in the n-type pillar layer 3c.

A gate electrode 12 is formed on the n-type pillar layer 3c which is sandwiched between p-type base layers 8 (or the n-type pillar layer 3c is arranged adjacent to the p-type base layer 8) and the gate electrode extends partially over the neighboring p-type base layers 8, and the n⁺-type source layers 9 which are formed over respective surfaces of the neighboring p-type base layers 8 with a gate insulation film 11 extending therebetween. An interlayer insulation film 13 is formed to cover an upper portion of the gate electrode 12.

The source electrode 15 is electrically connected to the n⁺-type source layers 9 and the p-type base layers 8 via opening portions formed in the interlayer insulation films 13, i.e., between adjacent gate electrodes 12 and gate insulation films. The p⁺-type contact layers 10 are formed over the surface of the p-type base layer 8 between adjacent n⁺-type source layers 9. The source electrode 15 is electrically connected to the p-type base layers 8 via the p⁺-type contact layers 10. The source electrode 15 is insulated from the gate electrodes 12 by the interlayer insulation films 13. The concentration of p-type impurity in the p⁺-type contact layers 10 is higher than the concentration of p-type impurity in the p-type base layer. The drain electrode 14 is electrically connected to the n⁺-type semiconductor layer.

The gate insulation films 11 and the interlayer insulation films 13 are made of silicon oxide, silicon nitride or silicon oxynitride, for example. The gate electrodes 12 may be made of any materials provided that the material has conductivity, for example, polysilicon.

In FIG. 1, on a right side of the cross-sectional view of the semiconductor device according to the embodiment, a profile of the concentration of p-type impurity in the p-type pillar layer 4c taken along a line A-A in the cross-sectional view is shown. The concentration of p-type impurity exhibits a minimum value at a connecting portion, i.e., at the interface between, the neighboring p-type diffusion layers 4b, and exhibits a maximum value between the neighboring minimum values which are located generally in the vicinity of the center of the respective p-type impurity diffusion layers. A minimum value of the concentration of p-type impurity in a connecting portion between the p-type diffusion layer 4b which constitutes an uppermost portion of the p-type pillar layer 4c and the p-type base layer 8 is larger than a minimum value of the concentration of p-type impurity in a connecting portion between the neighboring p-type impurity diffusion layers 4b in the p-type pillar layer 4c.

Next, a method of manufacturing a semiconductor device according to the embodiment is explained. A step of forming the first p-type impurity layers is performed as shown in FIG. 2A. A mask M1, in which a plurality of opening portions are formed in a spaced-apart manner from each other at fixed intervals (hereinafter, first intervals) is formed over a surface of the n⁻-type semiconductor layer 2 which itself is formed over the n⁺-type semiconductor substrate 1. Through these opening portions, a p-type impurity, for example, boron (B) is selectively implanted into the surface of the n⁻-type semiconductor layer 2 by ion implantation. Due to such implantation, a plurality of first p-type impurity layers 4a are formed in the n⁻-type semiconductor layer 2 below the surface of the n⁻-type semiconductor layer 2 and spaced from one another at the above-mentioned first intervals. The plurality of first p-type impurity layers 4a are arranged along the first direction, parallel to the surface of the n⁻-type semiconductor layer 2. Thereafter, the mask M1 is removed.

Next, as shown in FIG. 2B, a step of forming first n-type impurity layers is performed. A mask M2 in which opening portions are formed at the center of adjacent first p-type impurity layers 4a impurity layers is formed over the surface of the n⁻-type semiconductor layer 2. Through the opening portions, an n-type impurity, for example, phosphorus (P) is selectively injected into the surface of the n⁻-type semiconductor layer 2 by ion implantation. Due to such ion implantation, a plurality of first n-type impurity layers 3a are spaced from one another along the first direction at the above-mentioned first interval. The first n-type impurity layers 3a are formed in the n⁻-type semiconductor layer 2 below the surface of the n⁻-type semiconductor layer 2 such that each first n-type impurity injection layer 3a is located at the center of the gap or spacing between neighboring first p-type impurity layers 4 aim purity layers. Thereafter, the mask M2 is removed.

Next, a step of forming the first epitaxial layers is performed. As shown in FIG. 3A, the first n⁻-type epitaxial layer 5 is formed over the n⁻-type semiconductor layer 2 by epitaxial growth. The first n⁻-type epitaxial layer 5 is formed of an n⁻-type semiconductor having the concentration of n-type impurity lower than that of the n⁺-type semiconductor substrate.

Next, a step of forming the second p-type impurity layers is performed. As shown in FIG. 3B, the above-mentioned mask M1 is formed over the surface of the first epitaxial layer 5 such that the respective opening portions are arranged directly above the plurality of respective first p-type impurity layers 4a. Through the opening portions of the mask M1, a p-type impurity 4 is selectively injected into the surface of the first epitaxial layer 5 by ion implantation. Due to such ion implantation, the plurality of second p-type impurity layers 4a are formed within the first epitaxial layer 5 below the surface of the first epitaxial layer 5 such that the second p-type impurity layers 4a are arranged in a spaced-apart manner from each other at the above-mentioned first intervals along the above-mentioned first direction. Simultaneously, the plurality of respective second p-type impurity layers 4a are arranged directly above the plurality of respective first p-type impurity layers 4a in the second direction, which is perpendicular to the surface of the n⁻-type semiconductor layer 2. Thereafter, the mask M1 is removed.

Next, a step of forming second n-type impurity layers 3a is performed. As shown in FIG. 3C, the above-mentioned mask M2 is formed over the surface of the first epitaxial layer 5 such that the respective opening portions are arranged directly above the plurality of respective first n-type impurity layers 3a. Through the opening portions of the mask M2, an n-type impurity 3 is selectively injected into the surface of the first epitaxial layer 5. Due to such ion implantation, the plurality of second n-type impurity layers 3a are formed within the first epitaxial layer 5 below the surface of the first epitaxial layer 5 such that the plurality of second n-type impurity layers 3a are arranged in a spaced-apart manner from each other at the above-mentioned first intervals along the above-mentioned first direction. Simultaneously, the plurality of respective second n-type impurity layers 3a are arranged directly above the plurality of respective first n-type impurity layers 3a in the second direction, which is perpendicular to the surface of the n⁻-type semiconductor layer 2. Thereafter, the mask M2 is removed.

The series of steps including the step of forming the first epitaxial layer, the step of forming the second p-type impurity injection layer, and the step of forming the second n-type impurity injection layer is performed once, twice or more. In this embodiment, as shown in FIG. 4A, the series of steps is repeated three times. As a result, the first p-type impurity injection layer 4a and the second p-type impurity injection layer 4a are constituted of four p-type impurity layers 4a. In the same manner, the first n-type impurity injection layer 3a and the second n-type impurity injection layer 3a are also constituted of four n-type impurity layers 3a.

Next, the step of forming the second epitaxial layer is performed. As shown in FIG. 4B, the second epitaxial layer 6 which is made of semiconductor having a concentration of n-type impurity lower than that of the n⁺-type semiconductor substrate 1 is formed by epitaxial growth over the first epitaxial layer 5, after the above-mentioned series of steps (the first epitaxial layer formed as the third layer). The film thickness of the second epitaxial layer 6 is smaller than the film thicknesses of the first epitaxial layers 5.

Next, heat treatment is performed. As shown in FIG. 5A, by diffusing the impurity (dopants) in the plurality of first n-type impurity layers 3a and the impurity (dopants) in the plurality of second n-type impurity layers 3a, the plurality of n-type impurity diffusion layers 3b are formed from the plurality of first n-type impurity layers 3a and the plurality of second n-type impurity layers 3a. The plurality of n-type impurity diffusion layers 3b are connected to each other in the second direction (perpendicular to the surface of the substrate 1) thus forming the plurality of n-type pillar layers 3c. The plurality of n-type pillar layers 3c extend along the second direction and are arranged along the first direction.

Simultaneously, by diffusing an impurity in the plurality of first p-type impurity layers 4a and an impurity in the plurality of second p-type impurity layers 4a respectively, the plurality of p-type impurity diffusion layers 4b are formed from the plurality of first p-type impurity layers 4a and the plurality of second p-type impurity layers 4a. The plurality of p-type impurity diffusion layers 4b are connected to each other in the second direction thus forming the plurality of p-type pillar layers 4c. The plurality of p-type pillar layers 4c extend along the second direction, and are arranged along the first direction. As a result, the plurality of p-type pillar layers 4c and the plurality of n-type pillar layers 3c are arranged alternately along the first direction.

Next, a step for forming the p-type semiconductor layer is performed. As shown in FIG. 5B, the p-type base layers 8 are formed such that the respective p-type base layers 8 extend from the surface of the second epitaxial layer 6 into the second epitaxial layer 6 and are electrically connected with the plurality of respective p-type pillar layers 4c. For example, using a mask not shown in the drawing, a p-type impurity is selectively injected into the surface of the second epitaxial layer by ion implantation. Thereafter, by applying heat treatment, the above-mentioned p-type impurity is diffused into the inside of the second epitaxial layer 6 from the surface of the second epitaxial layer 6. Due to such treatment, the p-type base layers 8 are formed such that the p-type base layers 8 are connected to the upper portions of the p-type impurity diffusion layers 4b which constitute the uppermost portions of the p-type pillar layer 4c respectively.

Next, as shown in FIG. 1, a step of selectively forming the n⁺-type source layers 9 on surfaces of the p-type base layers 8 is performed. Then, a step of forming the gate electrodes 12 over the n⁺-type source layers 9, the p-type base layers 8 and the n-type pillar layers 3c which are arranged adjacent to the p-type pillar layers 4c connected to the p-type base layers 8 respectively via the gate insulation films 11 is performed. Thereafter, the step of forming the source electrode 15 which is electrically connected to the n⁺-type source layers 9 and the p-type base layers 8 is performed. Then, the step of forming the drain electrode 14 on the back surface of the n⁺-type semiconductor substrate 1 is performed, such as by physical or chemical vapor deposition techniques.

Next, a semiconductor device according to a comparative example is described with reference to the graph on the right hand side of FIG. 6, wherein a profile of the concentration of p-type impurity in the p-type pillar layer 4c in the depth direction taken along a line B-B in a cross-sectional view differs from that of the semiconductor device according to the embodiment. In the semiconductor device according to the first embodiment, the minimum value of the concentration of p-type impurity in the connecting portion, i.e., the interface between the p-type impurity diffusion layer 4b which constitutes the uppermost portion of the p-type pillar layer 4c and the p-type base layer 8 is larger than a minimum value of the concentration of p-type impurity in the connecting portion between the p-type impurity diffusion layers 4b which are arranged adjacent to each other in the second direction in the p-type pillar layer 4c. To the contrary, in the semiconductor device according to the comparative example, a minimum value of the concentration of p-type impurity in the connecting portion between the p-type impurity diffusion layer 4b which constitutes the uppermost portion of the p-type pillar layer 4c and the p-type base layer 8 is smaller than a minimum value of the concentration of p-type impurity in the connecting portion between the p-type impurity diffusion layers 4b arranged adjacent to each other in the second direction in the p-type pillar layer 4c.

This difference in minimum value of the concentration of p-type impurity is brought about by the difference between the method of manufacturing a semiconductor device according to the first embodiment and the method of manufacturing a semiconductor device according to the comparative example. In the method of manufacturing a semiconductor device according to the comparative example, a final first epitaxial layer 5 is formed in place of forming the second epitaxial layer 6 shown in FIG. 4B. That is, the first epitaxial layer 5 according to the comparative example has a larger film thickness than the second epitaxial layer 6 according to the first embodiment. In other words, the final epitaxial layer of the embodiment, second epitaxial layer 6, is thinner than the final epitaxial layer 5 of the comparative example. The method of manufacturing a semiconductor device according to the comparative example differs from the method of manufacturing a semiconductor device according to the first embodiment only with respect to such a point. Except for such a point, there is no difference in structure of the semiconductor device and the method of manufacturing a semiconductor device between the first embodiment and the comparison example.

Accordingly, in the method of manufacturing a semiconductor device according to the comparison example, when the p-type base layer 8 is formed in the same manner as the method of manufacturing a semiconductor device according to the first embodiment, the diffusion of p-type impurity from the p-type base layer 8 does not sufficiently reach the p-type diffusion layer 4b which constitutes the uppermost portion of the p-type pillar layer 4c. Accordingly, the minimum value of the concentration of p-type impurity in the connecting portion between the p-type base layer 8 and the p-type diffusion layer 4b which constitutes the uppermost portion of the p-type pillar layer 4c, the minimum value of the semiconductor device according to the comparison example becomes smaller than that of the semiconductor device according to the first embodiment.

As a result, in the semiconductor device according to the first embodiment, the concentration of p-type impurity in a portion of the p-type base layer 8 directly below the n⁺-type source layer 9 is higher than that of the semiconductor device according to the comparative example. Accordingly, the semiconductor device according to the first embodiment exhibits a smaller voltage drop in the p-type base layer 8 for a hole current generated by avalanche breakdown compared to the semiconductor device according to the comparative example and hence, the drain source current required to cause the parasitic diode formed of the n⁺-type source layer 9 and the p-type base layer 8 turn on is higher. FIG. 7 shows a characteristic observed between a drain-source voltage and a drain-source current of the semiconductor device according to the first embodiment, and a characteristic observed between a drain-source voltage and a drain-source current of the semiconductor device according to the comparative example. The semiconductor device according to the first embodiment can sustain a larger drain-source current flow before the parasitic diode forms as compared to the semiconductor device according to the comparative example. That is, the semiconductor device according to the first embodiment possesses higher avalanche resistance than the semiconductor device according to the comparative example.

In the method of manufacturing a semiconductor device according to this embodiment, as described above, the second epitaxial layer 6 where the p-type base layer 8 is formed is formed with a thickness smaller than a thickness of the first epitaxial layer 5 which is necessary for forming the p-type impurity diffusion layer 4b and the n-type impurity diffusion layer 3b. Accordingly, in forming the p-type base layer 8 by p-type impurity diffusion, a bottom of the p-type base layer 8 is easily extended into the p-type impurity diffusion layer 4b which constitutes the uppermost portion of the p-type pillar layer 4c. As a result, the concentration of p-type impurity is increased at a connecting portion between the p-type base layer 8 and the p-type impurity diffusion layer 4b which constitutes the uppermost portion of the p-type pillar layer 4c and hence, even when an electric current flows at the time of avalanche breakdown, a parasitic diode formed of the n⁺-type source layer 9 and the p-type base layer 8 is formed at a higher current. That is, the avalanche resistance is enhanced.

Also in the method of manufacturing a semiconductor device according to the comparison example, by increasing an injection amount (implanted dopant quantity) of the p-type impurity by ion implantation and by increasing the diffusion of the p-type impurity by heat treatment at the time of forming the p-type base layer 8, the concentration of p-type impurity in the connecting portion between the p-type base layer 8 and the p-type impurity diffusion layer 4c which constitutes the uppermost portion of the p-type pillar layer 4c can be set higher than the concentration of p-type impurity in the connecting portion between the p-type diffusion layers 4b arranged adjacent to each other in the second direction in the p-type pillar layers 4c. However, in the method of manufacturing a semiconductor device according to the comparative example, the gap formed between the p-type base layers 8 positioned adjacent to each other in the first direction becomes short and hence, resistance generated when an electron flows into the n-type pillar layer 3c from the channel layer is increased so that the ON resistance of the semiconductor device is increased. In the method of manufacturing a semiconductor device according to the first embodiment, such increase of the ON resistance is not generated.

As has been explained heretofore, with the use of the method of manufacturing a semiconductor device according to the first embodiment, the avalanche resistance can be enhanced while maintaining the high breakdown strength and the low ON resistance of the semiconductor device.

In the method of manufacturing a semiconductor device according to the first embodiment, in forming the p-type impurity layers 4a and the n-type impurity layers 3a, the ion implantation of p-type impurity is performed prior to the ion implantation of n-type impurity. However, the order of ion implantation may be reversed.

### Second Embodiment

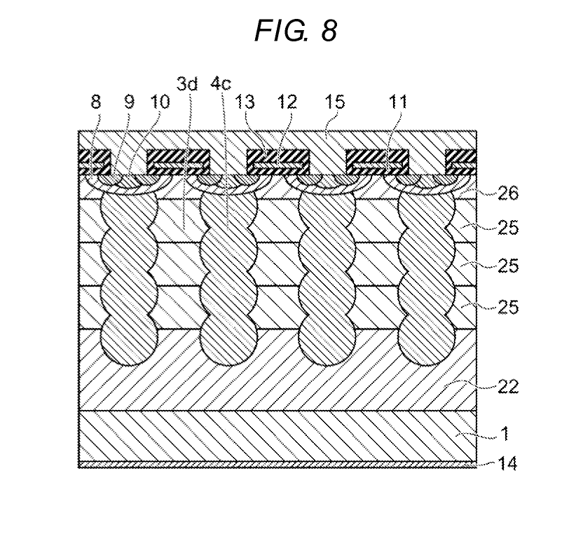

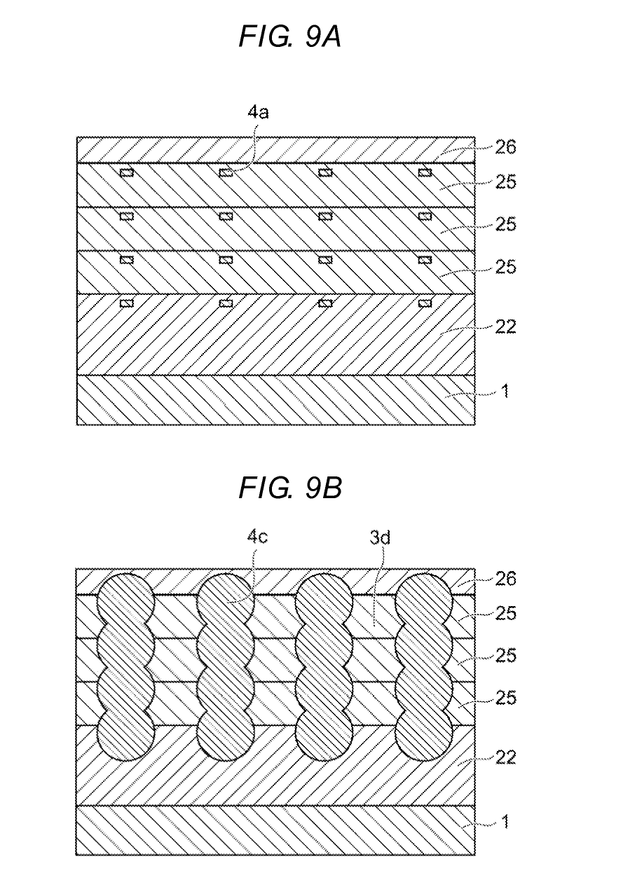

A semiconductor device and a method of manufacturing a semiconductor device according to the second embodiment are explained in conjunction with FIG. 8, FIG. 9A and FIG. 9B. FIG. 8 is a cross-sectional view of the semiconductor device according to the second embodiment. FIG. 9A and FIG. 9B are views respectively showing essential parts of the semiconductor device according to the second embodiment in cross section formed in several steps of the method of manufacturing a semiconductor device. In the second embodiment, the constitutions identical with the constitutions explained in conjunction with the first embodiment are given same reference numerals or symbols and the explanation of these constitutions is omitted. In the second embodiment, the explanation is made mainly with respect to the differences between the first embodiment and the second embodiment.

As shown in FIG. 8 in cross section, in the semiconductor device according to the second embodiment, an n-type pillar layer 3d is not formed by connecting a plurality of n-type impurity diffusion layers in the second direction, but is instead formed of an n-type semiconductor layer 22, first n-type epitaxial layers 25 and a second n-type epitaxial layer 26 which are sandwiched between neighboring p-type pillar layers 4c among a plurality of p-type pillar layers 4c, each of which is formed of a plurality of p-type impurity diffusion layers formed in each n-type epitaxial layer 25.

Further, the n-type semiconductor layer 22, the first n-type epitaxial layers 25 and the second n-type epitaxial layer 26 according to the second embodiment respectively have the concentration of n-type impurity higher than that of the n⁻-type semiconductor layer 2, the first n⁻type epitaxial layers 5 and the second n⁻type epitaxial layer 6 according to the first embodiment. Such concentration of n-type impurity is set so as to maintain the balance between p-type impurity and an n-type impurity in the super junction structure by making the total amount of n-type impurity in the n-type pillar layers 3d according to the second embodiment substantially equal to the total amount of n-type impurity in the n-type pillar layers 3c according to the first embodiment.

The semiconductor device according to the second embodiment differs from the semiconductor device according to the first embodiment with respect to the above-mentioned point. Corresponding to such difference, the method of manufacturing a semiconductor device according to the second embodiment differs from the method of manufacturing a semiconductor device according to the first embodiment also with respect to the following points. As shown in FIG. 9, in the method of manufacturing a semiconductor device according to the second embodiment, it is unnecessary to form the n-type impurity layers 3a. Accordingly, in the manufacturing steps of the method of manufacturing a semiconductor device according to the second embodiment, steps up to the step of forming the second epitaxial layer 26 in the manufacturing steps of the method of manufacturing a semiconductor device according to the first embodiment are performed while omitting the step of forming the first n-type impurity injection layer and the step of forming the second n-type impurity injection layer in the manufacturing steps of the method of manufacturing a semiconductor device according to the first embodiment.

Thereafter, as a result of the step of performing heat treatment, as shown in FIG. 9B, a plurality of p-type pillar layers 4c are formed by connecting the plurality of p-type impurity diffusion layers 4b which are formed by diffusing a p-type impurity from the plurality of first p-type impurity layers 4a and the plurality of second p-type impurity layers 4a in the second direction. The plurality of n-type pillar layers 3d are constituted of the n-type semiconductor layer 22, the first n-type epitaxial layers 25 and the second n-type epitaxial layer 26 which form gaps between the plurality of p-type pillar layers 4c. That is, the plurality of n-type pillar layers 3d are formed of portions of the n-type semiconductor layer 22, the first n-type epitaxial layers 25 and the second n-type epitaxial layer 26 which are sandwiched between the neighboring p-type pillar layers among the plurality of p-type pillar layers 4c. The manufacturing steps which follow the above-mentioned step correspond to the manufacturing steps of the manufacturing method according to the first embodiment.

Also in the method of manufacturing a semiconductor device according to the second embodiment, the second epitaxial layer 26 in which the p-type base layers 8 are formed is formed with a thickness smaller than a thickness of the first epitaxial layer 25 necessary for forming the p-type impurity diffusion layer 4b. Accordingly, also in the method of manufacturing a semiconductor device according to the second embodiment, in the same manner as the method of manufacturing a semiconductor device according to the first embodiment, the avalanche resistance can be enhanced while maintaining the high breakdown strength and the low ON resistance of the semiconductor device.

Further, in the method of manufacturing a semiconductor device according to the second embodiment, compared to the method of manufacturing a semiconductor device according to the first embodiment, the step of forming the first n-type impurity layers 3a and the step of forming the second n-type impurity layers 3a become unnecessary and hence, a manufacturing cost of the semiconductor device can be largely reduced.

### Third Embodiment

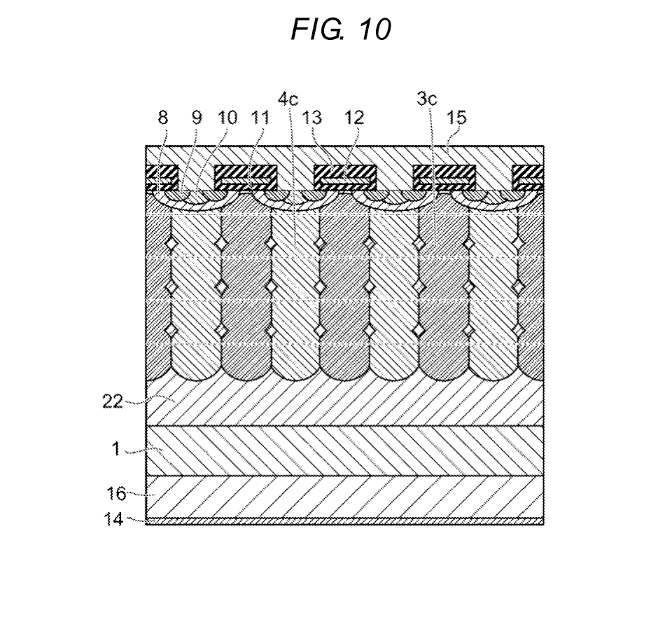

A semiconductor device according to the third embodiment is explained in conjunction with FIG. 10. FIG. 10 is a cross-sectional view of the semiconductor device according to the third embodiment. In FIG. 10, the constitutions identical with the constitutions explained in conjunction with the first embodiment are given same numerals or symbols and the explanation of these constitutions is omitted. In the third embodiment, the explanation is made mainly with respect to the differences between the semiconductor device according to the third embodiment and the semiconductor device according to the first embodiment.

The semiconductor device according to the third embodiment, as shown in FIG. 10, corresponds to the case where the semiconductor device according to the first embodiment is applied to an IGBT. That is, the semiconductor device according to the third embodiment includes a p⁺-type collector layer 16 which is constituted of a p⁺-type semiconductor between an n⁺-type semiconductor substrate 1 and a drain electrode 14 (a collector electrode in the IGBT). The third embodiment differs from the first embodiment with respect to such a point. Accordingly, the method of manufacturing a semiconductor device according to the first embodiment is also applicable to the semiconductor device according to the third embodiment.

The semiconductor device and the method of manufacturing a semiconductor device according to the third embodiment can also acquire the substantially same advantageous effects as the semiconductor device and the method of manufacturing a semiconductor device according to the first embodiment.

The semiconductor device and the method of manufacturing a semiconductor device according to the second embodiment are also applicable to the IGBT in the same manner as the third embodiment.

In the embodiments explained heretofore, the explanation is made with respect to a case where the p-type pillar layer 4c is constituted of the impurity diffusion layers 4b in four stages. However, the exemplary embodiment is not limited to such a constitution. The number of stages of the p-type impurity diffusion layers 4b which constitute the p-type pillar layer 4c is adjusted corresponding to the breakdown strength of the semiconductor device.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a semiconductor device comprising:
providing a substrate;
epitaxially forming a first layer on a first side of the substrate and implanting a first type dopant therein in a regularly spaced pattern;
epitaxially forming a second layer on the substrate and implanting a first type dopant therein in the regularly spaced pattern;
epitaxially forming a third layer, having a thickness less than the thickness of the second layer, over the second layer; and implanting the first type dopant therein; and
annealing the substrate to diffuse the first type dopant in the first, second and third layers to form spaced columns of diffused first type dopants in the first and second layers,
wherein the doped region is formed in the third layer corresponding to the locations of the columns of diffused first type dopant, the doped region in the third layer extending at least to the diffused dopant column in the second layer, and the dopant concentration at the interface between the doped region of the third layer and the diffused dopant of the second layer is the location of the highest dopant concentration in the column.

2. The method of manufacturing a semiconductor device according to claim 1, wherein the first layer and second layer are epitaxially grown as doped layers having an second conductivity type dopant therein.

3. The method of manufacturing a semiconductor device according to claim 1, further comprising:
implanting a dopant of an opposite conductivity type as the first type dopant into the first layer after forming the first layer in locations intermediate of the locations where the first type dopant was implanted; and
annealing the substrate to form columns of second conductivity type dopant between adjacent columns of first type dopant.

4. The method of manufacturing a semiconductor device according to claim 1, further comprising: forming a source layer, having a second conductivity type dopant than that of the first type therein, over the third layer.

5. The method of manufacturing a semiconductor device according to claim 4, wherein a source layer is disposed to either side of a column of the second conductivity type.

6. The method of manufacturing a semiconductor device according to claim 1, wherein the first layer and second layer are doped epitaxial layers of a second conductivity type different from the first type dopant.

7. The method of manufacturing a semiconductor device according to claim 1, wherein n additional epitaxial layers are formed between the first and the second layer, where n is a positive whole number.

8. The method of manufacturing a semiconductor device according to claim 1, wherein the concentration of the second conductivity type dopant, different than the first type dopant, in the second layer is greater than the concentration of the second conductivity type dopant in the first layer.

9. The method of manufacturing a semiconductor device according to claim 1, further comprising: forming an electrode on a second side of the substrate.

10. The method of manufacturing a semiconductor device according to claim 1, further comprising:
forming a doped layer of the first type on the second surface of the substrate; and
forming an electrode on the layer of the first type formed on the second surface of the substrate.

11. The method of manufacturing the semiconductor device according to claim 1, wherein the diffused dopant columns of the first type dopant in the first layer extend only partially through the depth of the first layer.

12. The method of manufacturing a semiconductor device according to claim 11, wherein the diffused dopant columns of the first type dopant in the second layer extends through the second layer.

13. A method of manufacturing a semiconductor device comprising:
selectively forming a plurality of first impurity layers of a second conductivity type on a surface of a first semiconductor layer of a first conductivity type by ion implantation;
forming a first epitaxial layer of a first conductivity type on the first semiconductor layer;
selectively forming a plurality of second impurity layers of a second conductivity type on a surface of the first epitaxial layer by ion implantation such that the plurality of second impurity layers are positioned above the first impurity layers of a second conductivity type in the second direction perpendicular to the surface of the first semiconductor layer;
forming a second epitaxial layer of a first conductivity type having a thickness smaller than a thickness of the first epitaxial layer in the second direction on the first epitaxial layer;
forming a plurality of pillar layers of a second conductivity type by bonding the first impurity layers of a second conductivity type and the second impurity layers of a second conductivity type to each other in the second direction by heat treatment;
forming a second semiconductor layer of a second conductivity type which is brought into contact with the pillar layers of a second conductive type on a surface of the second epitaxial layer;
selectively forming a third semiconductor layer of a first conductivity type on a surface of the second semiconductor layer;
forming a gate electrode on the second semiconductor layer and the third semiconductor layer by way of a gate insulation film;
forming a first electrode which is electrically connected to the second semiconductor layer and the third semiconductor layer; and
forming a second electrode which is electrically connected to the first semiconductor layer.

14. The method of manufacturing a semiconductor device according to claim 13, further comprising:
forming a first impurity injection layer of a first conductivity type by ion implantation on a surface of the first semiconductor layer of a first conductivity type between the first impurity layers of a second conductivity type arranged adjacent to each other; and
forming a second impurity injection layer of a first conductivity type by ion implantation on a surface of the first epitaxial layer between the second impurity layers of a second conductivity type arranged adjacent to each other; wherein
the first impurity injection layer of a first conductivity type and the second impurity injection layer of a first conductivity type are joined to each other in the second direction by heat treatment thus forming a plurality of pillar layers of a first conductivity type.

15. The method of manufacturing a semiconductor device according to claim 13, wherein the forming of the second semiconductor layer comprises: selectively injecting an impurity of a second conductivity type into the surface of the second epitaxial layer by ion implantation; and performing heat treatment so as to diffuse the impurity of a second conductivity type whereby the second semiconductor layer is formed by diffusion of the impurity of a second conductivity type.

16. The method of manufacturing a semiconductor device according to claim 14, further comprising:
forming a doped layer of the second type on the second surface of the substrate, intermediate of the substrate and the second electrode.

17. A semiconductor device, comprising:
a substrate;
an epitaxial layer formed on the substrate:
a plurality of regularly spaced regions of a first dopant type extending inwardly of the epitaxial layer; and
a plurality of regularly spaced regions of a second dopant type extending inwardly of the epitaxial layer and between the regularly spaced regions of the first dopant type,
wherein the concentration of dopant in the regions of the second dopant type varies in the depth direction of the epitaxial layer, and the highest dopant concentration is located adjacent the surface of the epitaxial layer furthest from the substrate.

18. The semiconductor device of claim 17, wherein the epitaxial layer comprises a plurality of individual film layers; and
the thickness of the film layer furthest from the substrate is smaller than the thickness of the film layer upon which the film layer furthest from the substrate is formed.

19. The semiconductor device of claim 18, wherein the second type dopant is a diffused implanted dopant.

20. The semiconductor device of claim 18, wherein the second type dopant is implanted into a first type dopant layer.
